(19) United States
(12) Patent Application Publication
(10) Pub. No.: US 2023/0384425 A1
(43) Pub. Date: Nov. 30, 2023

(54) LIDAR UNIT WITH STRAY LIGHT REDUCTION SYSTEM

(71) Applicant: LG INNOTEK CO., LTD., Seoul (KR)

(72) Inventors: Brian Edward PICCIONE, Yardley, PA (US); Samuel Richard WILTON, Levittown, PA (US); Christopher John TROWBRIDGE, Dexter, MI (US); Allen Massie EARMAN, Santa Clara, CA (US); Mark Allen ITZLER, Princeton, NJ (US)

(73) Assignee: LG INNOTEK CO., LTD., Seoul (KR)

(21) Appl. No.: 17/752,189

(22) Filed: May 24, 2022

(51) Int. Cl. G01S 7/481; G02B 3/00; G02B 5/00; G01S 17/931; G01S 17/10; G01S 7/484; G01S 7/486

(52) U.S. Cl. CPC G01S 7/4816; G02B 3/0037; G02B 5/003; G01S 17/931; G01S 17/10; G01S 7/484; G01S 7/4868

(57) ABSTRACT

Disclosed herein are system and method embodiments for generating a signal indicative of light received by a lidar unit that has a high signal-to-noise ratio. For example, the system includes a focal plane assembly (FPA) with an array of detectors. The FPA includes a micro-lens array (MLA) with an input surface that is configured to receive light, and an array of optics forming an output surface arranged along a focal plane that is configured to focus the light on the array of detectors. A mask is disposed over an outer portion of at least one of the input surface and the output surface. The mask is configured to absorb stray light and reduce optical noise within the MLA.

### TECHNICAL FIELD

One or more embodiments relate to a sensor system with one or more light absorbing surfaces for reducing stray internal light reflections.

### BACKGROUND

A photodetector is an optoelectronic device that converts incident light or other electromagnetic radiation in the ultraviolet (UV), visible, and infrared spectral regions into electrical signals. Photodetectors may be used in a wide array of applications, including, for example, fiber optic communication systems, process controls, environmental sensing, safety and security, and other imaging applications such as light detection and ranging applications. High photodetector sensitivity can enable detection of faint signals returned from distant objects, however, such sensitivity to optical signals can be susceptible to high optical noise sensitivities. Accordingly, the proposed systems and methods of the present disclosure provide solutions to reduce optical noise sensitives in photodetector devices.

### SUMMARY

In one embodiment, a focal plane assembly (FPA) is provided with an array of detectors. The FPA includes a micro-lens array (MLA) with an input surface that is configured to receive light, and an output surface arranged along a focal plane and configured to focus the light on the array of detectors. A mask is disposed over an outer portion of at least one of the input surface and the output surface. The mask is configured to absorb stray light and reduce optical noise within the MLA.

In another embodiment, a micro-lens array (MLA) is provided with an input surface that is configured to receive light, and an output surface arranged along a focal plane and configured to focus the light on the array of detectors. A mask is disposed over an outer portion of at least one of the input surface and the output surface. The mask is configured to absorb stray light.

In yet another embodiment, a lidar unit is provided with at least one emitter that is configured to emit light pulses away from a vehicle. A housing includes: an opening that is configured to receive light; and an outlet that is opposite the opening and aligned along an optical axis. At least one lens is supported by the housing and aligned along the optical axis to focus the light. The lidar unit also includes an array of detectors and a lens array with an input surface and an array of optics. The lens array includes an input surface that is aligned with the at least one lens and configured to receive the light. The lens array also includes an array of optics that form an output surface that is configured to focus the light on the array of detectors. A mask is disposed over an outer portion of at least one of the input surface and the output surface, and the mask is configured to absorb stray light and reduce optical noise within the lens array.

### BRIEF DESCRIPTION OF THE DRAWINGS

FIG. 1 is a schematic diagram of an exemplary autonomous vehicle (AV) system with a light detection and ranging (“lidar”) unit, in accordance with aspects of the disclosure.

FIG. 2 is an exemplary architecture of the lidar unit of the AV system, in accordance with aspects of the disclosure.

FIG. 3 is a side view of a photodetector receiver assembly, in accordance with aspects of the disclosure.

FIG. 4A is a front view of a focal plane assembly (FPA) of the photodetector receiver assembly, in accordance with aspects of the disclosure.

FIG. 4B is an enlarged view of a portion of the FPA of FIG. 4A, illustrating a micro-lens assembly, in accordance with aspects of the disclosure.

FIG. 5A is a perspective section view of the FPA of FIG. 4A, taken along section line V-V, in accordance with aspects of the disclosure.

FIG. 5B is an enlarged view of a portion of the FPA of FIG. 5A, in accordance with aspects of the disclosure.

FIG. 6A is a front view of an FPA of the receiver assembly of FIG. 3, in accordance with aspects of the disclosure.

FIG. 6B is an enlarged view of a portion of the FPA of FIG. 6A, in accordance with aspects of the disclosure.

FIG. 7 is a section view of the FPA of FIG. 6A, taken along section line VII-VII, illustrating a light absorbing surface, in accordance with aspects of the disclosure.

FIG. 8 is a section view of the FPA according to another embodiment, illustrating another light absorbing surface, in accordance with aspects of the disclosure.

FIG. 9 is a section view of the FPA according to another embodiment, illustrating another light absorbing surface, in accordance with aspects of the disclosure.

FIG. 10 is a section view of the FPA according to another embodiment, illustrating another light absorbing surface, in accordance with aspects of the disclosure.

FIG. 11 is a section view of the FPA according to another embodiment, illustrating multiple light absorbing surfaces, in accordance with aspects of the disclosure.

In the drawings, like reference numbers generally indicate identical or similar elements. Additionally, generally, the left-most digit(s) of a reference number identifies the drawing in which the reference number first appears.

### DETAILED DESCRIPTION

As required, detailed embodiments are disclosed herein; however, it is to be understood that the disclosed embodiments are merely exemplary and may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

As noted herein, an example use of photodetectors is in light detection and ranging applications (e.g., within lidar systems). For example, one of the most desirable attributes of a lidar system is long range detection, which depends on photodetector sensitivity. Long range detection may be achieved using a very sensitive photodetector. High photodetector sensitivity can enable detection of faint signals returned from distant objects, hence, providing a lidar device that is capable of detecting objects at long ranges. However, sensitivity to optical signals may also correlate with sensitivity to optical noise. Due to this correlation, it is desirable for a device deploying a photodetector (e.g., lidar) to reduce the optical noise sensitivity.

One such example of noise sensitivity may be due to stray light reflections within a photodetector receiver (e.g., lidar receiver). Specifically, within a receiver's focal plane assembly (FPA), discrete micro-lens arrays that are used to enhance optical fill factor may produce total internal reflections that can cause a die to function as a light pipe by carrying stray light long distances from the source location. This can result in an optical blooming effect, a type of optical noise which can temporarily blind a particularly sensitive detector to other signals.

According to some aspects, the disclosed embodiments limit the stray light reflections that are trapped within a micro-lens array (MLA), thereby maintaining high photodetector sensitivity levels while reducing the optical blooming (i.e., stray light reflections). For example, aspects of the disclosure provide an MLA with optical characteristics designed to reduce the effects of stray light that is trapped within the MLA. According to some aspects, the MLA may include masking layers placed at an input surface, an output surface, or both surfaces of the MLA to reduce optical noise in the FPA by absorbing stray light. According to some aspects, the masking layers may further be placed at outer regions, inner regions, or both regions of either the input surface and/or output surface of the MLA.

Reduction of optical noise inside an FPA can improve the detection of an incident signal at the detector (e.g., a returned light signal). According to some aspects described herein, reduction of the optical noise by the disclosed MLA can lead to the reduction/attenuation of the bloom effect at the detector. This reduction can significantly improve the detection capability of the detector especially when the returned light signal is received from a highly reflective object (e.g., road signs (directional signs, yield signs, stop signs, etc.)) that include embedded reflective material, any other objects that include embedded reflective material, or other highly reflective objects.

A lidar assembly (e.g., the lidar unit 200) including the disclosed FPA may improve its detection capabilities and detection accuracy due to the reduced noise affecting the signal. This performance improvement of the lidar provides further benefits for an autonomous vehicle (AV), such as AV 102, operating the lidar unit 200. For example, the lidar unit 200 of AV 102 may receive a light signal reflected from an object exhibiting high reflectivity (e.g., a mirror, glass, or objects embedded with highly reflective material such as stop signs and other road signs). In this case, the lidar unit 200 deploying the disclosed systems and methods may reduce the bloom effect such that objects at long distance can still be detected while attenuating noise signals produced at the MLA. In this example, the lidar unit 200 can achieve high detection sensitivity while reducing susceptibility to noisy signals and improving signal to noise ratio (SNR) of the received signal prior to performing digital signal processing (DSP) applications.

According to some aspects, the performance improvement of the lidar unit 200 further translates to downstream improvement in DSP speed and accuracy. For example, by eliminating the noisy signals, an on-board computer device (e.g., the AV system 104) may utilize less bandwidth to filter out the noise using signal processing techniques. Additionally, the AV system 104 may utilize less bandwidth to check detection accuracy of the lidar output. By the same token, the AV system 104 may also utilize less bandwidth to compare detection accuracy of the lidar output with other sensor outputs in a detection stack (e.g., radar and camera data). According to some aspects, a lidar unit 200 implementing the disclosed embodiments may provide more accurate output signals that feed into the AV's detection, tracking, and prediction stacks. For example, improving the accuracy of the data stacks received by the AV system 104 can reduce the delay that the AV system 104 may exhibit in processing a compromised detection signal from the lidar unit 200 or in reconciling such signal with other detection signals received at the same time instance (e.g., from cameras or radar systems (not shown)). Minimizing computational costs associated with processing detection signals can improve the processing capabilities of the AV system 104, reduce latency, and free up the AV system's 104 bandwidth to perform other downstream navigation tasks like prediction and motion planning tasks.

According to some aspects, the lidar unit's 200 performance improvement may further translate to downstream improvement in detection and classification capabilities—thereby improving the navigation capabilities of the AV 102. For example, the AV 102 may be able to navigate a geographic location without having the lidar unit 200 be blinded due to an optical bloom, and do so in a continuous manner. Because of the reduced bloom effect described herein, the AV 102 may also navigate the geographic location while being able to detect and classify a highly reflective object. It can be appreciated that the above benefits are merely exemplary and other benefits to detection, compute, and downstream applications such as autonomous driving and navigation may be within the scope of this disclosure as would be appreciated by those skilled in the art.

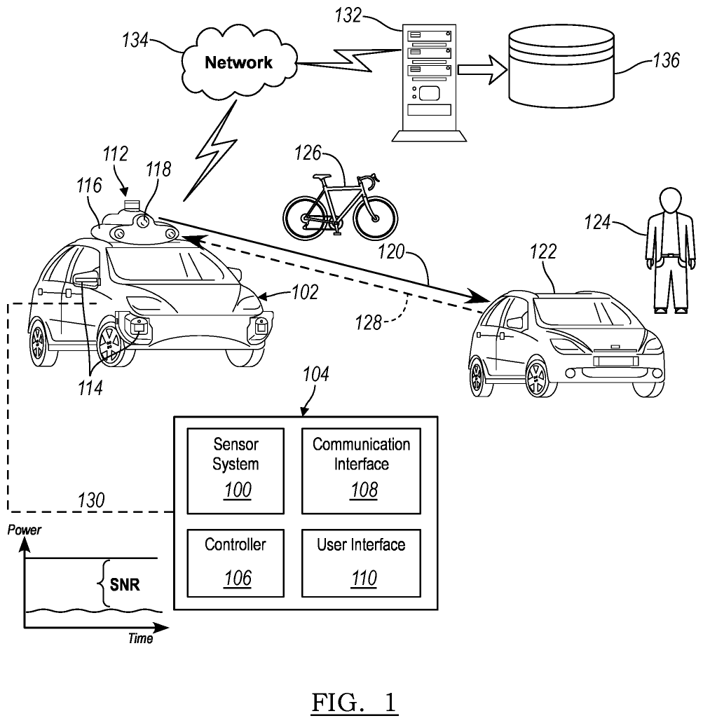

With reference to FIG. 1, a sensor system with one or more light absorbing surfaces is illustrated in accordance with one or more embodiments and generally referenced by numeral 100. The sensor system 100 includes multiple sensor assemblies that are mounted to an autonomous vehicle (AV) 102 and are included in an AV system 104. The AV system 104 also includes a controller 106, a communication interface 108 for communicating with other systems and devices, and a user interface 110 for communicating with a user.

The sensor system 100 includes a top sensor assembly 112 and multiple side sensor assemblies 114 for monitoring an environment external to the AV 102. The top sensor assembly 112 is mounted to a roof of the AV 102 and includes a light detection and ranging (lidar) unit according to one or more embodiments. The lidar unit includes one or more emitters 116 and one or more detectors 118. The emitters 116 transmit light pulses 120 away from the AV 102. The transmitted light pulses 120 are incident on one or more objects, e.g., a remote vehicle 122, a pedestrian 124, and a cyclist 126, and reflect back toward the top sensor assembly 112 as reflected light pulses 128. The top sensor assembly 112 guides the reflected light pulses 128 toward the detectors 118, which provide corresponding light signals 130 to the controller 106. The controller 106 processes the light signals 130 to determine a distance of each object 122, 124, 126, relative to the AV 102. The top sensor assembly 112 includes absorbing material that is disposed over one or more surfaces to absorb stray light to reduce optical noise incident on the detectors 118, thereby increasing the signal-to-noise ratio of the light signals 130.

The side sensor assemblies 114 include cameras, e.g., visible spectrum cameras, infrared cameras, etc., for monitoring the external environment. The top sensor assembly 112 and the side sensor assemblies 114 may each include a lidar unit, one or more cameras, and/or a radar unit.

The AV system 104 may communicate with a remote computing device 132 over a network 134. The remote computing device 132 may include one or more servers to process one or more processes of the technology described herein. The remote computing device 132 may also communicate with a database 136 over the network 134.

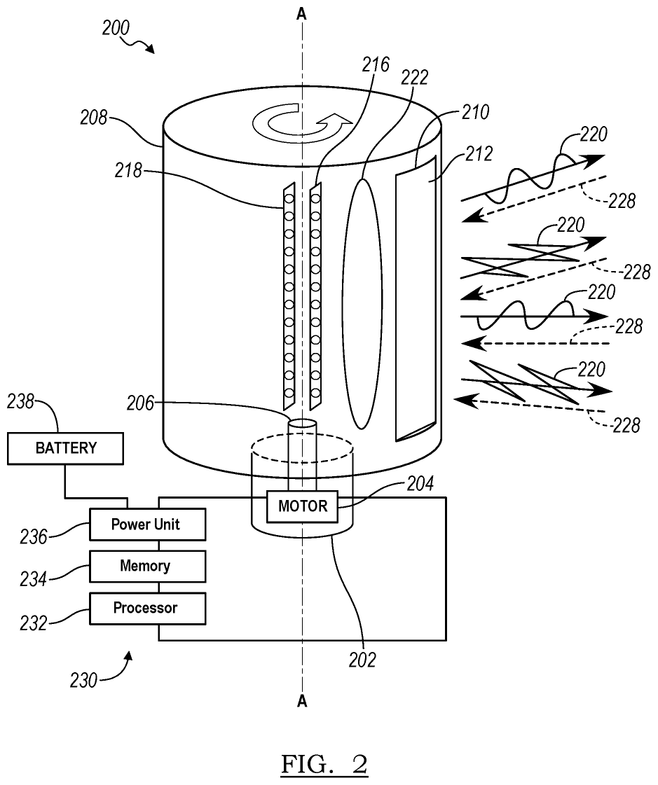

FIG. 2 illustrates an exemplary architecture of a lidar unit 200, such as the lidar unit of the top sensor assembly 112, according to one or more embodiments. The lidar unit 200 includes a base 202 that is mounted to the AV 102, e.g., to a roof of the AV 102 as shown in FIG. 1. The base 202 includes a motor 204 with a shaft 206 that extends along a vertical axis A-A. The lidar unit 200 also includes a housing 208 that is secured to the shaft 206 and mounted for rotation relative to the base 202 about Axis A-A. The housing 208 includes an opening 210 and a cover or an aperture 212 that is secured within the opening 210. The aperture 212 is formed of a material that is transparent to light. Although a single aperture 212 is shown in FIG. 2, the lidar unit 200 may include multiple apertures 212.

The lidar unit 200 includes one or more emitters 216 for transmitting light pulses 220 through the aperture 212 and away from the AV 102 that are incident on one or more objects and reflect back toward the lidar unit 200. The lidar unit 200 also includes one or more light detectors 218 for receiving reflected light pulses 228 that pass through the aperture 212. The detectors 218 also receive light from external light sources, e.g., the sun. The emitters 216 and the detectors 218 may be stationary, e.g., mounted to the base 202, or dynamic and mounted to the housing 208. The emitters 216 may include laser emitter chips or other light emitting devices and may include any number of individual emitters (e.g., 8 emitters, 64 emitters, or 128 emitters). The emitters 216 may transmit light pulses 220 of substantially the same intensity or of varying intensities, and in various waveforms, e.g., sinusoidal, square-wave, and sawtooth. The lidar unit 200 may include one or more optical elements 222 to focus and direct light that is passed through the aperture 212. The detectors 218 may include a photodetector or an array of photodetectors that are positioned to receive the reflected light pulses 228. In one or more embodiments, the detectors 218 include passive imagers.

The lidar unit 200 includes a controller 230 with a processor 232 and memory 234 to control various components, e.g., the motor 204, the emitters 216, and the detectors 218. The controller 230 also analyzes the data collected by the detectors 218, to measure characteristics of the light received, and generates information about the environment external to the AV 102. The controller 230 may be integrated with another controller, e.g., the controller 106 of the AV system 104. The lidar unit 200 also includes a power unit 236 that receives electrical power from a vehicle battery 238, and supplies the electrical power to the motor 204, the emitters 216, the detectors 218, and the controller 230.

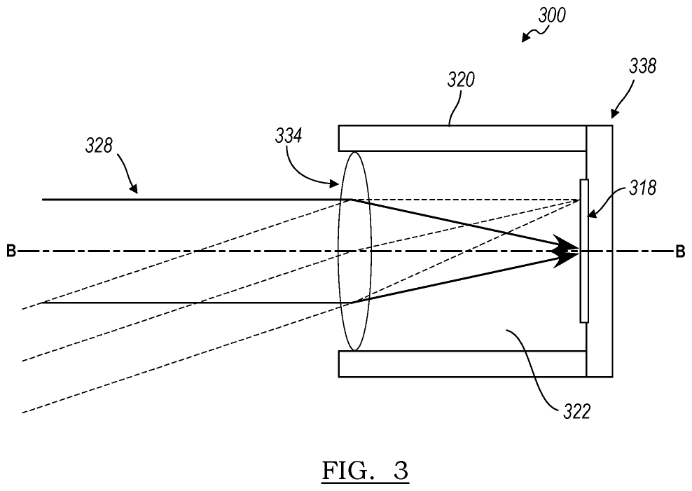

FIG. 3 illustrates a receiver assembly 300 of the lidar unit 200, according to one or more embodiments. The receiver assembly 300 includes a housing 320 that defines a cavity 322 that is aligned along an optical axis B-B. The receiver assembly 300 supports a lens 334 and a focal plane assembly (FPA) 338. In one or more embodiments, the lens 334 is a collimator lens. The lens 334 focuses the reflected light pulses 328 at a focal plane within the FPA 338.

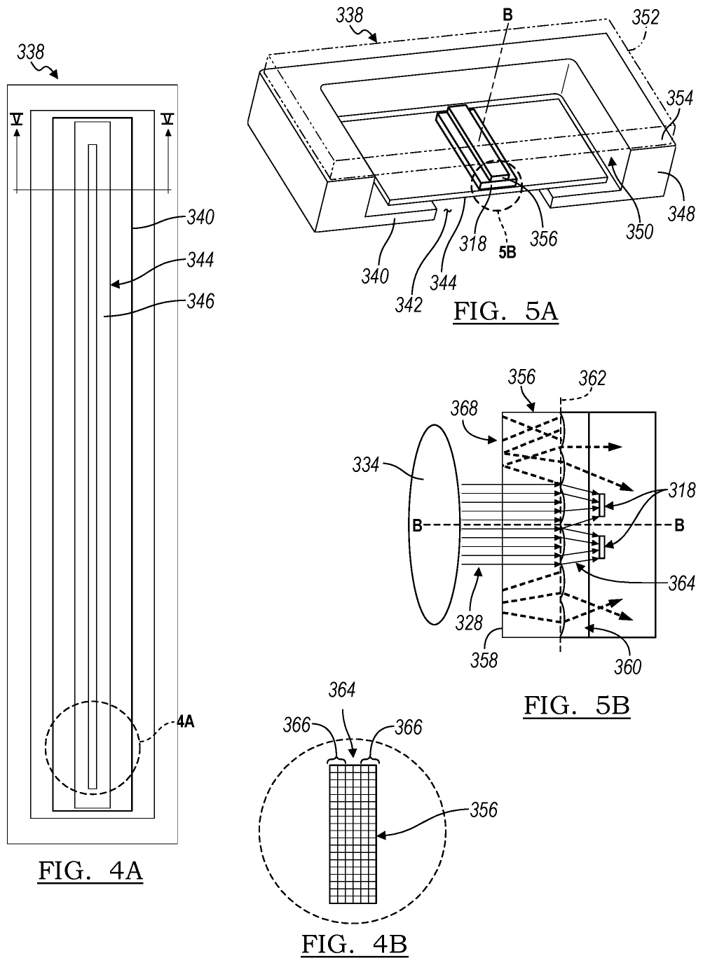

Referring to FIGS. 4A-5B, the FPA 338 supports an array of detectors 318, such as a photo-diode array (PDA). The FPA 338 includes a mounting surface, such as a base 340, that is formed in an elongate shape with a central opening 342. The FPA 338 also includes a circuit board assembly 344 that is mounted to the base 340 and disposed over the central opening 342. The array of detectors 318 are mounted to a top surface 346 of the circuit board assembly 344. The FPA 338 also includes sidewalls 348 that extend transversely from a periphery of the base 340 to define a cavity 350. The FPA 338 also includes a cover 352 that extends between a distal end 354 of the sidewalls 348 to enclose the cavity 350. The cover 352 is formed of an optically transparent material, such as glass and sapphire, to receive the reflected light pulses 328. The FPA 338 also includes a series of lenses, such as a micro-lens array (MLA) 356 that is mounted to the array of detectors 318.

With reference to FIG. 5B, the MLA 356 is formed in a rectangular packing configuration with a spherical, refractive, and single-sided lens profile, according to one or more embodiments. In the illustrated embodiment, the MLA 356 is formed in a single-sided plano-convex lens profile. The MLA 356 includes a planar input surface 358 that receives the reflected light pulses 328 from the lens 334. The MLA 356 also includes an array of convex optics 360 that form an output surface. The array of convex optics 360 are arranged along a focal plane 362. In other embodiments, the MLA 356 includes an array of optics formed at the input surface and a planar output surface, or an array of optics formed at both the input surface and the output surface (not shown).

The MLA 356 forms a plurality of apertures that extend between the planar input surface 358 and the output surface, including central apertures 364 and outer apertures 366 (shown in FIG. 4B). In one or more embodiments, each convex optic of the array of convex optics 360 is associated with an aperture, and each detector of the array of detectors 318 is optically aligned with one of the central apertures 364. The central apertures 364 and the outer apertures 366 are clear, or optically transparent. FIG. 5B illustrates two central apertures 364 that each focus the reflected light pulses 328 on an optically aligned detector of the array of detectors 318, as depicted by reflected light pulses 328 shown in solid line. The outer apertures 366 scatter the reflected light pulses 328 within the MLA 356 and around the cavity 350, as depicted by reflected light pulses shown in broken line, which may lead to optical noise.

Referring back to FIG. 3, the receiver assembly 300 may include sensitive detectors 318 to detect faint signals reflected from distant objects to achieve long range. However, such sensitive detectors 318 may be susceptible to optical noise due to stray light reflections. The MLA 356, which is used to enhance optical fill factor, functions as a light pipe due to internal reflection, carrying stray light long distances from the source location. This results in optical blooming, which is generally referenced by numeral 368 in FIG. 5B, a type of optical noise which can temporarily blind particularly sensitive detectors to other signals. In one or more embodiments, the receiver assembly 300 includes absorptive coatings on nonfunctional surfaces within the receiver assembly 300. However, this approach may not reduce stray light that is trapped within the MLA 356 or the circuit board assembly 344 of the FPA 338.

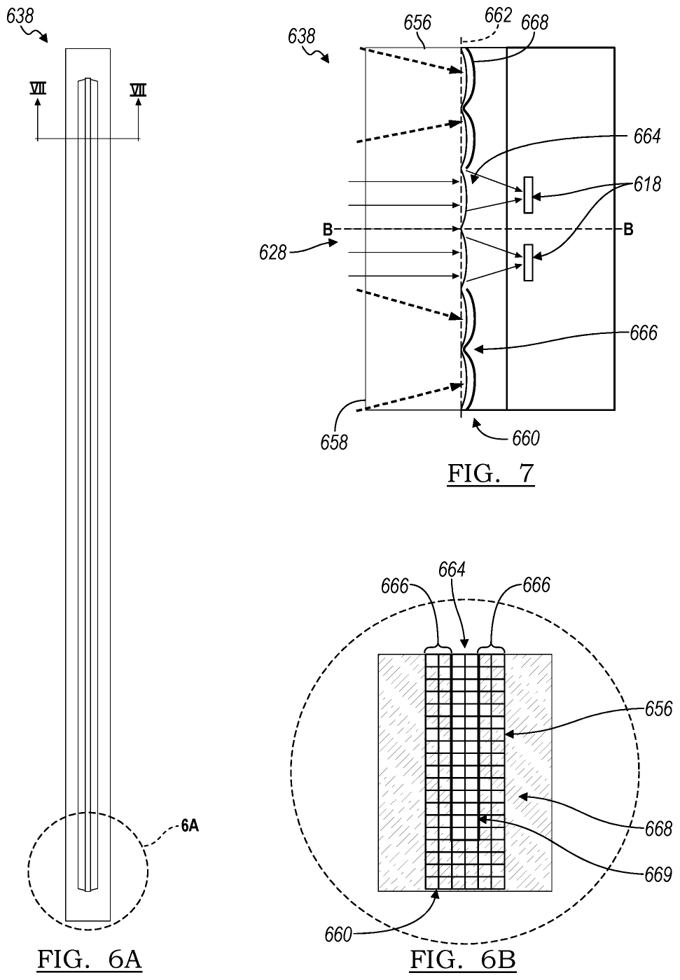

With reference to FIGS. 6A and 7, an FPA is illustrated in accordance with one or more embodiments and generally represented by numeral 638. The FPA 638 is similar to the FPA 338 described with reference to FIGS. 4A-5B. For example, like the FPA 338, the FPA 638 includes an array of detectors 618 and an MLA 656 that is formed in a planoconvex shape, with a planar input surface 658 and an array of convex optics 660 that are arranged along a focal plane 662 and form an output surface. The MLA 656 forms a plurality of apertures that extend axially between the planar input surface 658 and the output surface, including central apertures 664 and outer apertures 666. In one or more embodiments, each convex optic of the array of convex optics 660 is associated with an aperture, and each detector of the array of detectors 618 is optically aligned with one of the central apertures 664. The central apertures 664 are optically transparent apertures to focus the reflected light pulses 628 on the array of detectors 618. Unlike the outer apertures 366 of the FPA 338, the outer apertures 666 the FPA 638 are not optically transparent. Instead, the outer apertures 666 are coated with a mask 668 that absorbs stray light, which reduces optical noise. The mask 668 is formed with an opening 669 (shown in FIG. 6B) that is aligned with the central apertures 664. The mask 668, which is coincident with the focal plane 662, is formed of an opaque, or highly absorbing material, such as a black chrome or dielectric/metal stack. This configuration maximizes the absorption amount of stray light within the MLA 656 without any vignetting, or brightness reduction, of the primary signal.

FIGS. 8-11 illustrate additional embodiments of the FPA that include one or more surfaces that are coated with a material to absorb stray light. For example, FIG. 8 illustrates an FPA 838 that supports an array of detectors 818 and includes an MLA 856 with a partially transmitting, or slightly absorbent, material disposed over its output surface. The MLA 856 is formed in a planoconvex shape with a planar input surface 858 and an array of convex optics 860 that are arranged along a focal plane 862 and form an output surface. The MLA 856 forms a plurality of apertures that extend between the planar input surface 858 and the output surface, including central apertures 864 and outer apertures 866. In one or more embodiments, each convex optic of the array of convex optics 860 is associated with an aperture, and each detector of the array of detectors 818 is optically aligned with one of the central apertures 864. The MLA 856 includes a coating 868, that is disposed over the array of convex optics 860 including the central apertures 864 and outer apertures 866, that partially absorbs stray light to reduce optical noise. The material absorptivity of the coating 868 is between 0.1% and 10% such that the attenuation of the primary signal (e.g., the returned light signal) is minor due to only one surface interaction, but the attenuation of stray light is cumulative due to multiple surface interactions. This is a likely scenario in the case where total internal reflection of the MLA 856 “traps” stray light. This implementation highlights a difference between the stray light and the primary signal to attenuate stray light, i.e., the number of surface interactions. In one aspect, the primary signal may exit the MLA 856 having encountered the coating 868 only once as it traverses the MLA 856 on its way to the detectors 818. Conversely, stray light trapped inside the MLA 856 may continue to reflect off surfaces of the MLA 856, creating multiple interactions with the coating 868. In this regard, the coating 868 may attenuate the stray light with each encounter. Therefore, it can be appreciated that the multiple encounters with the coating 868 amount to a greater attenuation rate of the stray light as compared to the primary signal.

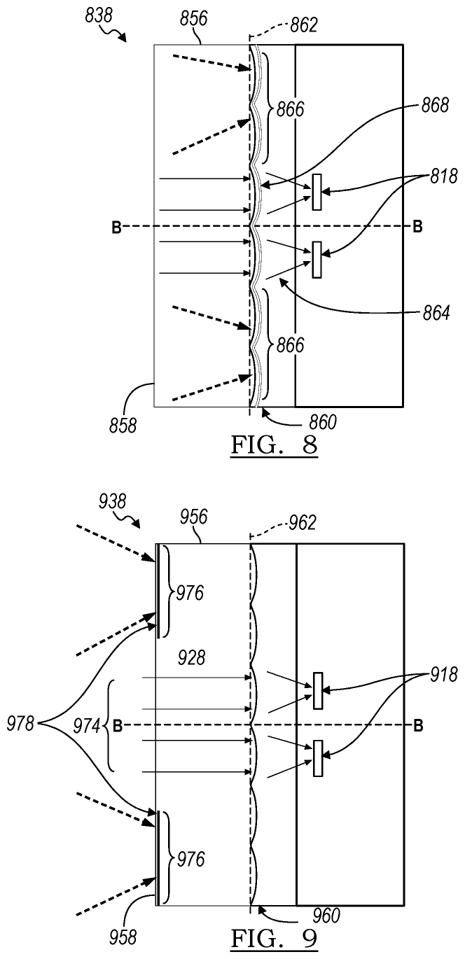

FIG. 9 illustrates an FPA 938 that supports an array of detectors 918 and includes an MLA 956 with an opaque material disposed over a portion of its input surface. The MLA 956 is formed in a planoconvex shape with a planar input surface 958 and an array of convex optics 960 that are arranged along a focal plane 962 and form an output surface. The planar input surface 958 includes a central region 974 and an outer region 976. The MLA 956 forms a plurality of apertures that extend between the planar input surface 958 and the output surface. In one or more embodiments, each convex optic of the array of convex optics 960 is associated with an aperture, and each detector of the array of detectors 918 is optically aligned with a central aperture extending from the central region 974. The central region 974 is optically transparent to focus the reflected light pulses 928 on the array of detectors 918. However, the outer region 976 is coated with a mask 978 that absorbs stray light, which reduces optical noise. Like the FPA 638, this configuration maximizes the amount of stray light which is absorbed without any vignetting, or brightness reduction, of the primary signal.

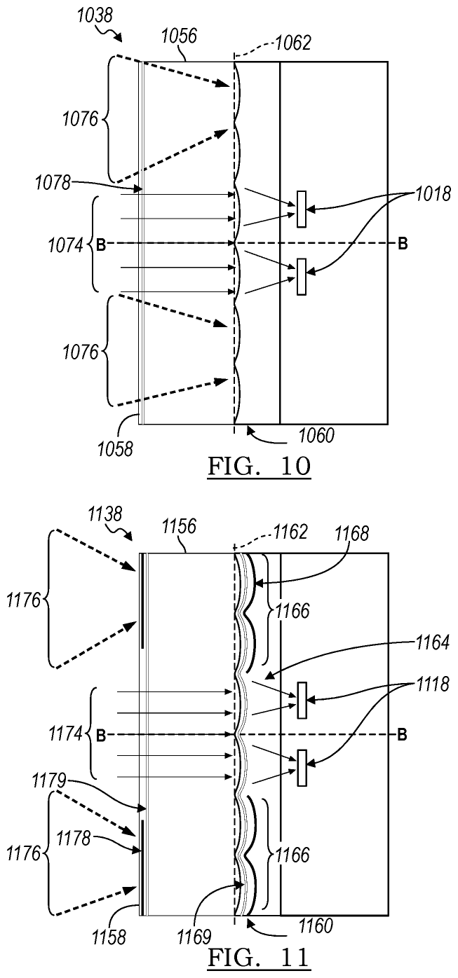

FIG. 10 illustrates an FPA 1038 that supports an array of detectors 1018 and includes an MLA 1056 with a partially transmitting material disposed across its input surface. The MLA 1056 is formed in a planoconvex shape with a planar input surface 1058 and an array of convex optics 1060 that are arranged along a focal plane 1062 and form an output surface. The MLA 1056 forms a plurality of apertures that extend between the planar input surface 1058 and the output surface. In one or more embodiments, each convex optic of the array of convex optics 1060 is associated with an aperture. The planar input surface 1058 includes a central region 1074 and an outer region 1076 that both include a coating 1078 that partially absorbs stray light to reduce optical noise. The material absorptivity of the coating 1078 is selected between 0.1% and 10% such that the attenuation of the primary signal is minor due to only one surface interaction, but the attenuation of stray light is cumulative due to multiple surface interactions. This is a likely scenario in the case where total internal reflection of the MLA 1056 “traps” stray light. Due to the significantly larger frequency of encounters with the coating 1078, the stray light experiences a greater degree of attenuation than the primary signal.

FIG. 11 illustrates an FPA 1138 that supports an array of detectors 1118 and includes an MLA 1156 with an opaque mask disposed over outer portions of its input surface and output surface, and a partially transmitting coating disposed across its input surface and its output surface. The MLA 1156 is formed in a planoconvex shape with a planar input surface 1158 and an array of convex optics 1160 that are arranged along a focal plane 1162 and form an output surface. The MLA 1156 forms a plurality of apertures that extend axially between the planar input surface 1158 and the output surface, including central apertures 1164 and outer apertures 1166. In one or more embodiments, each convex optic of the array of convex optics 1160 is associated with an aperture, and each detector of the array of detectors 1118 is optically aligned with one of the central apertures 1164. Like the FPA 638, the outer apertures 1166 are coated with a mask 1168 that absorbs stray light, which reduces optical noise. Like the FPA 838, the central apertures 1164 and the outer apertures 1166 include a coating 1169 that partially absorbs stray light to reduce optical noise. Like the FPA 938, the planar input surface 1158 includes a central region 1174 and an outer region 1176. The outer region 1176 is coated with a mask 1178 that absorbs stray light, which reduces optical noise. Like the FPA 1038, both the central region 1174 and the outer region 1176 include a coating 1179 that partially absorbs stray light to reduce optical noise.

Aspects of the present disclosure provide an MLA with optical characteristics designed to reduce the effects of trapped stray light. According to some aspects, the MLA may include masking layers placed at an input surface, an output surface, or both surfaces to reduce optical noise in the FPA by absorbing stray light. According to some aspects, masking layers may be placed at outer regions, inner regions, or both regions of either the input surface and/or output surface of the MLA, as described herein with respect to FIGS. 6-11. Reduction of optical noise inside an FPA can improve the detection of a returned light signal. Such improved detection can provide additional benefits to downstream application such as autonomous driving, transportation, mining, building, and construction applications where highly sensitive detection is preferred.

The term “vehicle” refers to any moving form of conveyance that is capable of carrying either one or more human occupants and/or cargo and is powered by any form of energy. The term “vehicle” includes, but is not limited to, cars, trucks, vans, trains, autonomous vehicles, aircraft, aerial drones and the like. An “autonomous vehicle” (or “AV”) is a vehicle having a processor, programming instructions and drivetrain components that are controllable by the processor without requiring a human operator. An autonomous vehicle may be fully autonomous in that it does not require a human operator for most or all driving conditions and functions, or it may be semi-autonomous in that a human operator may be required in certain conditions or for certain operations, or that a human operator may override the vehicle's autonomous system and may take control of the vehicle. Notably, the present solution is being described herein in the context of an autonomous vehicle. However, the present solution is not limited to autonomous vehicle applications. The present solution may be used in other applications such as robotic applications, radar system applications, metric applications, and/or system performance applications.

Based on the teachings contained in this disclosure, it will be apparent to persons skilled in the relevant art(s) how to make and use embodiments of this disclosure using data processing devices, computer systems and/or computer architectures. In particular, embodiments can operate with software, hardware, and/or operating system implementations other than those described herein.

It is to be appreciated that the Detailed Description section, and not any other section, is intended to be used to interpret the claims. Other sections can set forth one or more but not all exemplary embodiments as contemplated by the inventor(s), and thus, are not intended to limit this disclosure or the appended claims in any way.

While this disclosure describes exemplary embodiments for exemplary fields and applications, it should be understood that the disclosure is not limited thereto. Other embodiments and modifications thereto are possible, and are within the scope and spirit of this disclosure. For example, and without limiting the generality of this paragraph, embodiments are not limited to the software, hardware, firmware, and/or entities illustrated in the figures and/or described herein. Further, embodiments (whether or not explicitly described herein) have significant utility to fields and applications beyond the examples described herein.

Embodiments have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative embodiments can perform functional blocks, steps, operations, methods, etc. using orderings different than those described herein.

References herein to “one embodiment,” “an embodiment,” “an example embodiment,” or similar phrases, indicate that the embodiment described can include a particular feature, structure, or characteristic, but every embodiment can not necessarily include the particular feature, structure, or characteristic. Moreover, such phrases are not necessarily referring to the same embodiment. Further, when a particular feature, structure, or characteristic is described in connection with an embodiment, it would be within the knowledge of persons skilled in the relevant art(s) to incorporate such feature, structure, or characteristic into other embodiments whether or not explicitly mentioned or described herein. Additionally, some embodiments can be described using the expression “coupled” and “connected” along with their derivatives. These terms are not necessarily intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other. The breadth and scope of this disclosure should not be limited by any of the above-described exemplary embodiments, but should be defined only in accordance with the following claims and their equivalents.

While exemplary embodiments are described above, it is not intended that these embodiments describe all possible forms of the disclosure. Rather, the words used in the specification are words of description rather than limitation, and it is understood that various changes may be made without departing from the spirit and scope of the disclosure. Additionally, the features of various implementing embodiments may be combined to form further embodiments.

What is claimed is:

1. A focal plane assembly (FPA) comprising:
an array of detectors;
a micro-lens array (MLA) comprising:
an input surface configured to receive light; and
an output surface arranged along a focal plane and configured to focus the light on the array of detectors; and
a mask disposed over an outer portion of at least one of the input surface and the output surface, the mask being configured to absorb stray light and reduce optical noise within the MLA.

2. The FPA of claim 1, wherein the MLA comprises central apertures and outer apertures extending between the input surface and the output surface, and wherein each central aperture is optically aligned with one detector of the array of detectors.

3. The FPA of claim 2, wherein the mask comprises an opening that is aligned with the central apertures to limit any vignetting of the light focused on the array of detectors.

4. The FPA of claim 2, wherein the mask is formed of an opaque material and disposed over the outer apertures of the output surface.

5. The FPA of claim 2 further comprising a coating disposed over the central apertures and the outer apertures of the output surface.

6. The FPA of claim 1, wherein the mask is formed of an opaque material and disposed over the outer portion of the input surface.

7. The FPA of claim 1 further comprising a coating disposed over the input surface, wherein the coating is formed of a partially transmitting material.

8. The FPA of claim 1, wherein the MLA is formed with a plano-convex profile with a planar surface formed at one of the input surface and the output surface, and an array of convex optics formed at the other of the input surface and the output surface.

9. A receiver module comprising:
a housing with an opening configured to receive light and an outlet opposite the opening and aligned along an optical axis;
at least one lens supported by the housing and aligned along the optical axis to focus the light; and
an FPA according to claim 1, wherein the input surface of the MLA is aligned with the at least one lens to receive the light.

10. A lidar unit comprising:
a transmitter module with at least one emitter configured to emit light pulses away from a vehicle;
a receiver module according to claim 9, wherein the housing is configured to receive the light reflected off of an object external to the vehicle as reflected light pulses; and
wherein the array of detectors generates a light signal indicative of the reflected light pulses with a high signal-to-noise ratio based on the reduced optical noise present at the array of detectors.

11. A micro-lens array (MLA) comprising:
an input surface configured to receive light; and
an output surface arranged along a focal plane and configured to focus the light on an array of detectors; and
a mask disposed over an outer portion of at least one of the input surface and the output surface, the mask being configured to absorb stray light.

12. The MLA of claim 11 further comprising central apertures and outer apertures extending between the input surface and the output surface.

13. The MLA of claim 12, wherein the mask comprises an opening that is aligned with the central apertures to limit any vignetting of the light focused on the array of detectors.

14. The MLA of claim 12, wherein the mask is formed of an opaque material and disposed over the outer apertures of the output surface.

15. The MLA of claim 12 further comprising a coating disposed over the central apertures and the outer apertures of the output surface.

16. The MLA of claim 11, wherein the mask is formed of an opaque material and disposed over the outer portion of the input surface.

17. A lidar unit comprising:
at least one emitter configured to emit light pulses away from a vehicle;
a housing with an opening configured to receive light, and an outlet opposite the opening and aligned along an optical axis;
at least one lens supported by the housing and aligned along the optical axis to focus the light;
an array of detectors;
a lens array comprising:
an input surface aligned with the at least one lens and configured to receive the light; and
an array of optics forming an output surface configured to focus the light on the array of detectors; and
a mask disposed over an outer portion of at least one of the input surface and the output surface, the mask being configured to absorb stray light and reduce optical noise within the lens array.

18. The lidar unit of claim 17 further comprising a coating disposed over the input surface, wherein the coating is formed of a partially transmitting material.

19. The lidar unit of claim 17 further comprising a coating disposed over the output surface, wherein the coating is formed of a partially transmitting material.

20. The lidar unit of claim 17, wherein the lens array is formed with a planar input surface, and wherein each optic of the array of optics is formed with a convex profile.
